(19) United States
(12) Patent Application Publication
(10) Pub. No.: US 2001/0011861 A1
(43) Pub. Date: Aug. 9, 2001

(54) Method for compensating acoustic waves and device for carrying out the method

(76) Inventor: Hans Richter, Augsburg (DE)

Correspondence Address: KLAUS J. BACH & ASSOCIATES, PATENTS AND TRADEMARKS, 4407 TWIN OAKS DRIVE, MURRYSVILLE, PA, 15668, US

(21) Appl. No.: 09/813,873

(22) Filed: Mar. 21, 2001

Related U.S. Application Data
(63) Continuation of application No. PCT/EP99/06921, filed on Sep. 18, 1999.

(30) Foreign Application Priority Data
Sep. 21, 1998 (DE) 198 43 004.3
Jun. 19, 1999 (DE) 199 38 140.8

(51) Int. Cl. H01L 41/04

(52) U.S. Cl. 310/334; 310/322

(57) ABSTRACT

In a method and an apparatus for eliminating noise generated by a piezo actuator drive which includes in a housing a drive member, a drive shoe disposed adjacent the drive member, vibrating actuators forming drive elements and being connected to the drive shoe for engaging the drive shoe with the drive member and moving the drive shoe for driving the drive member, at least one additional actuator is disposed in the housing and operated at a frequency which is phase shifted with respect to at least the clamping actuators so as to cancel the noise waves generated during operation of the apparatus.

This is a continuation-in-part application of international application PCT/EP99/06921 filed Sep. 18, 1999 and claiming the priority of German applications 198 43 004.3 filed Sep. 21, 1998 and 199 38 140.8 filed Jun. 19, 1999.

### BACKGROUND OF THE INVENTION

The invention relates to a method for compensating acoustic waves which are generated by electric-actuator drives, particularly piezo actuator drives which include vibrating actuators arranged in a housing and which form a drive element including at least two actuators arranged at a right angle with respect to each other, and to an apparatus for performing the method.

It is known that sound waves can be extinguished by phase-shifted counter waves, wherein the counter waves are phase shifted with respect to the sound waves by a so-called phase frequency, generally 180° such that the maxima and the minima of the sound waves and respectively, counter waves overlap. It is however necessary that the counter wave generator follows accurately the sound or vibration frequencies to be compensated.

EP 0 552 344 B1 and DE 94 802 001 disclose electro-actuator drives which generate rotational or linear movements using vibrating piezo actuators. These or similar drives have the disadvantage that they generate undesirable noises which limit their applications.

### SUMMARY OF THE INVENTION

In a method and an apparatus for eliminating noise generated by a piezo actuator drive which includes in a housing a drive member, a drive shoe disposed adjacent the drive member, vibrating actuators forming drive elements and being connected to the drive shoe for engaging the drive shoe with the drive member and moving the drive shoe for driving the drive member, at least one additional actuator is disposed in the housing and operated at a frequency which is phase shifted with respect to at least the clamping actuators so as to cancel the noise waves generated during operation of the apparatus.

Advantageous embodiments of the invention will be described below on the basis of the accompanying drawings.

### BRIEF DESCRIPTION OF THE DRAWINGS

FIG. 1 is a side view of an electro-(piezo) actuator motor as disclosed in principle in DE 94 19 802.0U1 including however a separate acutator for sound compensation,

FIG. 2 is a cross-sectional view taken along line A-A of FIG. 1,

FIG. 2a is a cross-sectional view taken along line B-B of FIG. 1,

FIG. 3 is a side view of an embodiment including a noise compensating electro-actuator,

FIG. 4 is a cross-sectional view taken along line A-A of FIG. 3,

FIG. 5 is a side view of an embodiment with a noise-compensating second electro-actuator,

FIG. 5a is a cross-sectional view taken along line B-B of FIG. 5,

FIG. 6 is a cross-sectional view taken along line A-A of FIG. 5,

FIG. 7 is an overview for the control of the individual actuators of the motors for noise compensation,

FIG. 8 shows the sine wave-like sound waves phase shifted by 90° so that they cancel each other,

FIG. 9 shows a preferred embodiment of the drive arrangement, and

FIG. 10 is a view corresponding to that of FIG. 9 for the explanation of another mode of operation.

### DESCRIPTION OF PREFERRED EMBODIMENTS

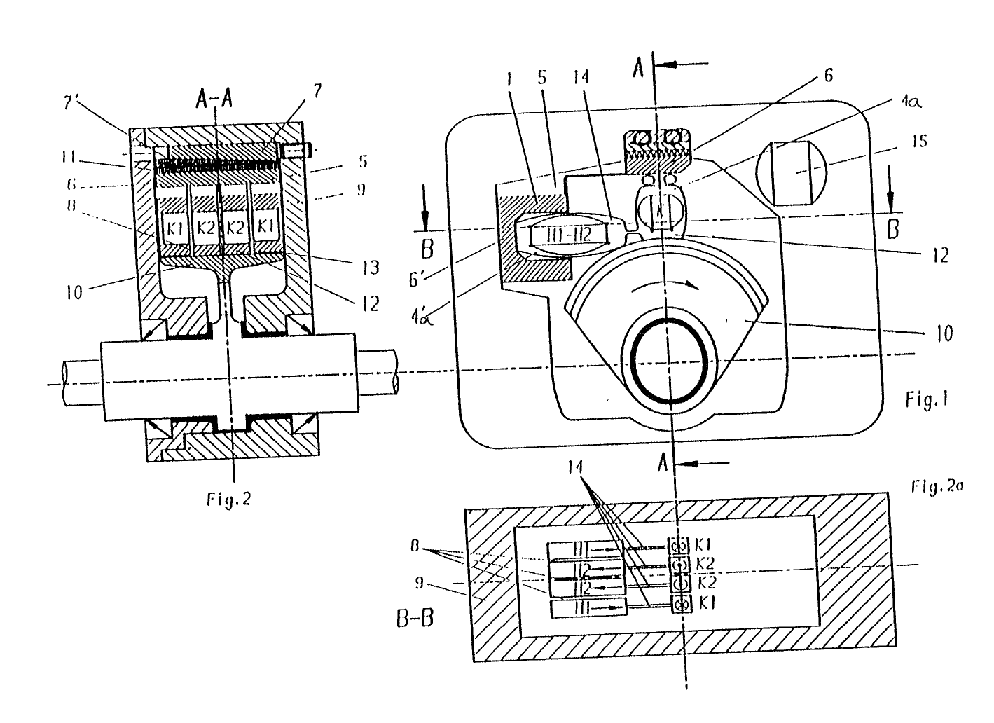

Based on a motor as disclosed in DE 94 19 802.0U1 a drive element 1 as shown in FIG. 1 comprises a pair of drive piezo elements H1, H2 and a pair of clamping piezo elements K1, and K2 (FIG. 2) firmly engaged each in a cage 4, and a cage 4′, respectively (FIG. 9), which extend rectangularly with respect to each other. In accordance with the embodiment shown in FIG. 2 four clamping piezo elements are disposed in an axial side-by-side relationship in a common drive element body 5 to form the drive element 1. The piezo element body 5 is continuous in outer bridge areas 6 and 6′ but is radially separated by slots 8 in the other areas, so that, in the embodiment as shown in FIGS. 1-4, four sections 14 are formed which can vibrate independently from one another actuated by the respective drive piezo elements H1 and H2. The bridge 6 for the clamping piezo elements K1 and K2 is biased by a wedging structure 7, 7′ with an intermediate rubber insert 11 in the direction toward the drive drum 10 and abuts the housing 9. The four operating shoes 12 of the four sections 14 of the drive element body 5 are engaged with the drive drum 10 in a cyclical manner.

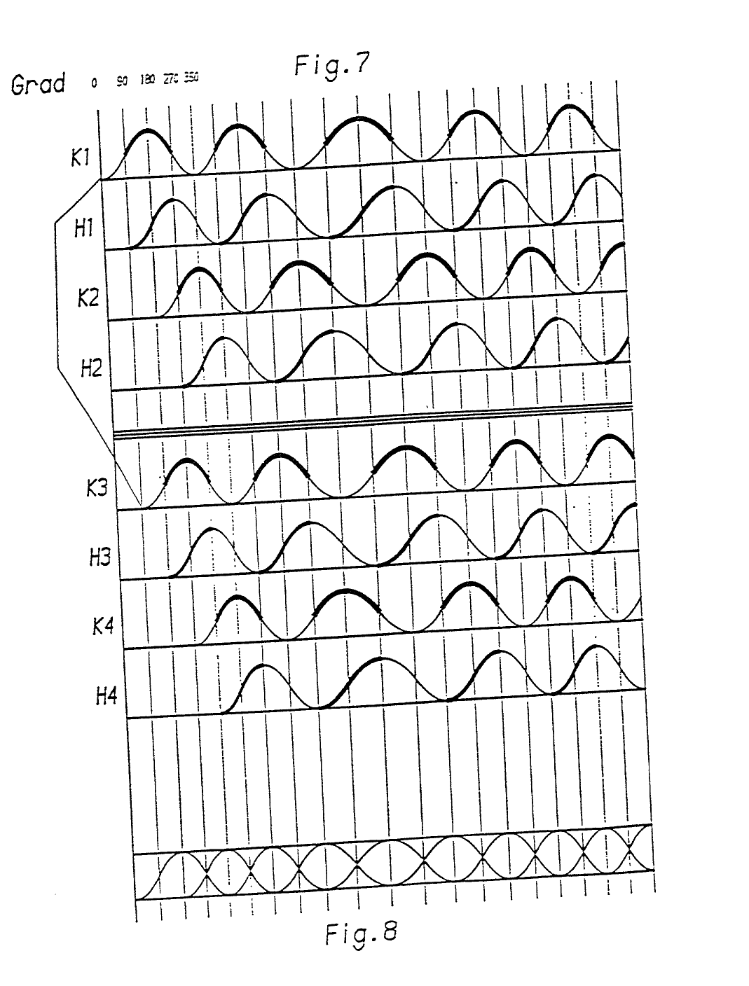

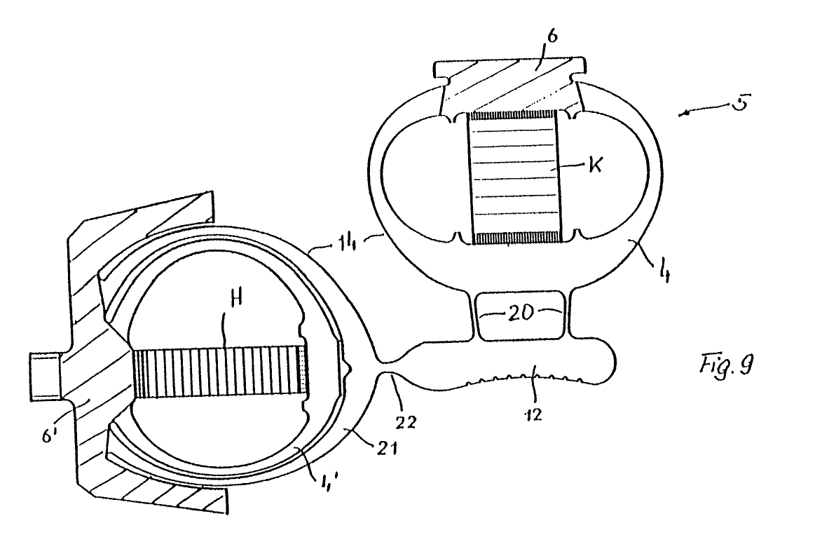

With the cyclical energization of the individual clamping and drive piezo elements in accordance with the diagram shown in FIG. 7,that is, the piezo elements indicated by the designations K1, H1, K2, H2, the operating shoes 12 of the drive element body 5 sequentially engage the drive drum 10 and move the drive drum 10, whereby the drive drum 10 is rotated. The clamping piezo elements K1 and K2 alternately form an air gap between the drive drum 10 and the operating shoe 12. In this way, the engagement force for engaging the clamping piezo elements K1 and K2 with the drive drum 10 is generated once by the piezo element K1 and then, in the next cycle, by the piezo element K2. When a gap 13 is formed between the drive drum 10 and the operating shoes 12, the operating shoes 12 can freely oscillate back by energization of the respective drive piezo elements H1 and H2 respectively. At the same time, the clamping piezo elements K1 and, respectively, K2, which then are in engagement with the drive member 10, are moved in the drive direction by energization of the respective drive piezo elements H1 or respectvely H2. In this way, a movement is achieved similar to the human walking which drives the drive drum 10. In particular, this movement is achieved as follows; When the clamping piezo elements K1 bias the operating shoes 12 of their two sections 14 into engagement with the drum 10 these two sections 14 are moved in drive direction by the associated drive piezo elements H1. At the same time, the operating shoes 12 of the two other sections 14 are disengaged from the drum 10 so that a gap 13 is formed between these operating shoes 12 and the drum while they move counter to the drive direction. In the next following tact, the situation is reversed.

The noises generated in this procedure can be compensated by an additional piezo element 15 disposed in the housing 9. However, this kind of compensation is optimal only with an optimally operating electronic control arrangement which senses and evaluates the sound waves essentially without time delay and converts that information into an energization of the piezo element for compensation of the emitted sound waves. The sound waves are generated primarily by the operating shoes hitting the drive drum 10. Preferably, the compensation piezo element 15 is energized so as to produce an opposite-phased sound wave. The effective operating direction of the piezo element 15 is preferably in the operating direction of the clamping piezo elements K1 and K2. The additional piezo element 15 may be energized at a frequency, which is twice the energization frequency of a clamping piezo element. Preferably, the phase of energization of the additional piezo element 15 is adjustable with respect to that of the clamping piezo elements.

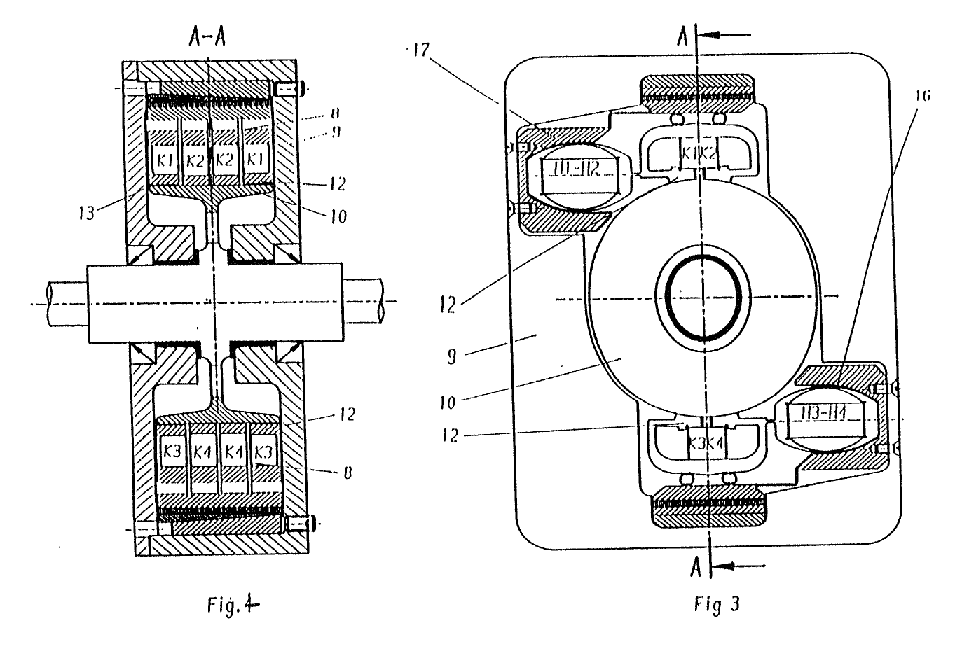

As shown in FIGS. 3 and 4, two drive elements 16 and 17 are provided. The two drive elements 16 and 17 are the same as the single drive element 1 shown in FIG. 1. They are controlled in accordance with the diagram of FIG. 7 in a phase-shifted manner, that is, phase-shifted by about 90° so that the sound waves generated by the two drive elements cancel each other substantially. This means that the clamping piezo element K3 of the drive element 17 is phase shifted by 90° relative to the clamping piezo element K1 of the drive element 16. The same applies to H3 with respect to H1, to K4 with respect to H1, to K4 with respect to K2 and to H4 with respect to H2. In this arrangement, which is applicable to rotational drives as well as to linear drives and wherein the drive element 16 is displaced by 180° with respect to the drive element 17, however, the sound is not completely cancelled. The reason herefor is that the two drive elements are arranged at a distance from each other so that the sound cannot be eliminated right where it is generated. With the unavoidable spacing between the drive elements some sound waves will escape and can not be cancelled.

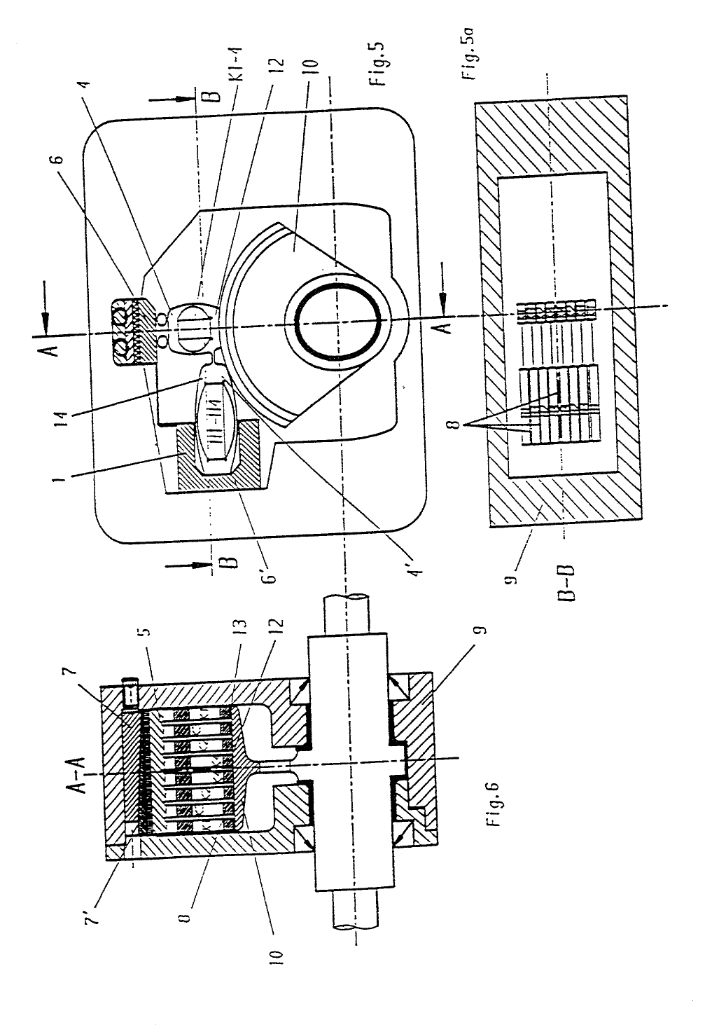

In the arrangement as shown in FIG. 5, the drive elements 1a and 1a′ are joined so that they operate essentially without spatial separation from each other. In this way, a highly effective sound cancellation can be achieved. To make such an arrangement, the clamping and drive piezo elements are relatively narrow (half as wide as in the other arrangements shown in FIG. 1 and FIG. 2). Sections of one piezo actuator element may be disposed adjacent to, or between, sections of another piezo actuator element, that is the piezo actuator elements may be intertwined. The sections 14, which are formed each by a clamping piezo element K and a drive piezo element H with associated engagement shoes 12, are separated by the slots 8. In accordance with diagram 7, the piezo elements K1, K2, H1, H2 are energized so as to vibrate at a 90° phase shift with respect to the piezo elements K3, K4, H3, H4. In this way, an optimal noise cancellation at the point of noise generation is achieved, that is complete noise cancellation is achieved in accordance with FIG. 8. No additional piezo element for the purpose of noise cancellation is needed.

FIG. 9 shows a drive element 5 in a cross-section taken along a slot 8. The cage 4 for the clamping piezo element K is elastic in the operating direction of the clamping piezo element and has the shape of an O. The cage 4 is connected to the drive shoe 12 by way of two thin webs 20. The webs 20 are arranged in a slightly wedge-like pattern such that they are closer together adjacent the drive shoe 12.

The cage 4′ of the drive piezo element also has the shape of an O and is elastic in the operating direction of the drive piezo element H. The end of the cage 4′ remote from the bridge 6′ is disposed adjacent another O-shaped cage 21, which is also elastic in the operating direction of the drive piezo element H. This additional cage 21 is connected to the drive shoe 12 by way of a thin web 22. It is also possible to connect the cage 4′ by means of the web 22 directly to the drive shoe 12.

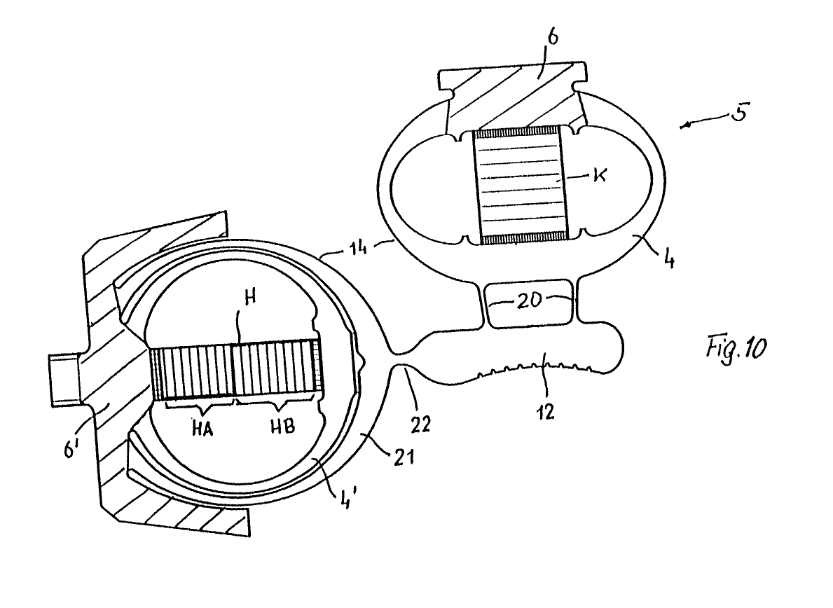

In the embodiment as shown in FIG. 10, each column of the drive piezo element pairs H1 and H2 is divided into the halves HA and HB, which are controlled independently with a phase frequency corresponding to the desired drive speed. The piezo elements of the halves HA and HB may have different polarities. All piezo elements of the halves HA and HB vibrate in resonance with each other at their full drive stroke but at different phases. The phase shift between the piezo elements of the two halves is adjustable, whereby the effective total stroke length is adjustable. The effective stroke length is the sum of the strokes of a first half HA or respectively, HB, plus the stroke of the other half HB or respectively, HA reduced by the phase difference. The mechanical stroke length can therefore be adjusted by changing the phase difference. In this way, all piezo elements can be operated at a frequency above 20 KHz, which is not audible. One of the halves HA or respectively, HB can therefore be considered to be the additional drive actuator element 15.

The phase shift between HA and HB may be one or several vibration periods so that, with subsequent strokes of for example HA, the stroke HA is doubled by the stroke HB or is cancelled out so that the overall stroke is adjustable between a doubled stroke length and zero.

It is possible in this way that all the piezo actuator elements vibrate at a frequency above the human hearing threshold of 20 kHz with full stroke when the drive piezo actuator elements are operated in a skipping fashion, that is, they are energized only with every second, third, fourth, etc. vibration of the clamping piezo actuator element.

What is claimed is:

1. A method of reducing the noise generated by a piezo-actuator drive including a drive member and a piezo-actuator drive means for driving said drive member, said method comprising the steps of providing as piezo-actuator drive means at least a first and a second piezo-actuator element and energizing said piezo-actuator elements in a phase-shifted manner such that the sound waves generated by said first and second piezo-actuator elements cancel each other.

2. A method according to claim 1, wherein at least said first piezo-actuator element includes at least a drive actuator element and a clamping actuator element and said second piezo-actuator element is energized at twice the frequency with which said clamping actuator element is operated.

3. A method according to claim 1, wherein the phase of the energization of said second piezo-actuator element is adjusted for greatest noise reduction.

4. A method according to claim 1, wherein a second actuator drive element is provided, which is essentially identical to said at least one actuator drive element, and both actuator drive elements are operated at the same frequency and the clamping actuator elements and drive actuator elements of the second drive element are energized at a phase shift of 90° with respect to the energization of the clamping and drive actuators of the one actuator drive element.

6. A method according to claim 5, wherein said drive piezos actuators are divided each in two halves which are independently energized and there is a phase shift between the two halves which is at least one vibration period.

7. A method according to claim 1, wherein, for controlling the operating speed of said actuator drive, energization of said drive actuators is selectable so as to skip at least one energization cycle of said clamping actuator.

8. An apparatus for compensating acoustic waves generated by a piezo-actuator drive comprising a movable drive member, a drive shoe arranged adjacent said drive member for engagement therewith, vibrating piezo actuator elements disposed adjacent said movable drive member and including at least one piezo drive element, each piezo drive element consisting of at least two pairs of piezo actuators, each pair comprising clamping actuators and drive actuators arranged at a right angle to each other, each of said clamping and drive actuators being connected to said drive shoe, the clamping actuators for acting on said drive shoe to engage said drive shoe with said drive element and said drive actuators for moving said drive shoe, and at least an additional piezo actuator, which is energized phase-shifted with respect to the clamping actuators and arranged such that its direction of effectiveness is essentially parallel to the operating direction of the clamping actuators.

9. An apparatus according to claim 8, wherein at least two piezo actuator drive elements are provided which are disposed opposite each other with respect to said drive member.

10. An apparatus according to claim 8, wherein said actuator elements include pairs of drive actuators, which are each divided into two halves that can be energized at variably different phases for controlling the drive stroke.

11. An apparatus according to claim 8, wherein each piezo actuator element includes an actuator element body provided, at the end opposite said drive shoe with a rigid bridge portion and the actuator element body is divided at its end adjacent said drive shoe by parallel slots into separate sections in each of which one of a clamping piezo actuator and a drive piezo actuator is disposed.

12. An apparatus according to claim 11, wherein said separate sections form cages which are elastic in the operating direction of said piezo actuator elements.

13. An apparatus according to claim 12, wherein said cages are connected to said drive shoe by way of elastic webs extending in the operating direction of the respective piezo actuator element.

14. An apparatus according to claim 8, wherein said two actuator drive elements are arranged adjacent one another at the same side of said drive member.

15. An apparatus according to claim 14, wherein the piezo actuators of said two actuator drive elements are arranged alternately so that they are intertwined for effective noise cancellation.
